(19) United States
(12) Patent Application Publication
(10) Pub. No.: US 2018/0262640 A1
(43) Pub. Date: Sep. 13, 2018

(54) IMAGE READING DEVICE AND SEMICONDUCTOR DEVICE

(71) Applicant: SEIKO EPSON CORPORATION, Tokyo (JP)

(72) Inventor: Shunichi SHIMA, Shiojiri-shi (JP)

(73) Assignee: SEIKO EPSON CORPORATION, Tokyo (JP)

(21) Appl. No.: 15/915,622

(22) Filed: Mar. 8, 2018

(30) Foreign Application Priority Data
Mar. 13, 2017 (JP) 2017-047456

(51) Int. Cl. H04N 1/193; H04N 5/378

(52) U.S. Cl. CPC H04N 1/1935; G06T 2200/28; H04N 1/1938; H04N 5/378

(57) ABSTRACT

An image reading device includes an image reading chip that reads an image, and an optical unit that forms a reduced image of the image on the image reading chip. The image reading chip includes: a first pixel and a second pixel that performs photoelectric conversion, and generates a first pixel signal and a second pixel signal, respectively; a first readout circuit and a second read out circuit that is electrically connected to the first pixel and the second pixel, respectively, and outputs a first readout signal and a second readout signal, respectively; and a control circuit that controls operations of the first readout circuit and the second readout circuit. The first pixel and the second pixel are provided side by side along a long side of the image reading chip. The first readout circuit, the second readout circuit, and the control circuit are provided along the long side.

### BACKGROUND

### 1. Technical Field

The present invention relates to image reading devices and semiconductor devices.

### 2. Related Art

Image reading devices (such as scanners) that use line sensors, and copy machines and multifunctional printers that have a print function in addition to a scan function have been developed. As a line sensor used in image reading devices, a line sensor configured to include photodiodes provided on a semiconductor substrate is used.

A line sensor used in an image reading device such as a scanner is constituted by a semiconductor chip in which a plurality of pixels each including one or a plurality of photodiodes are arranged side by side in one direction. Various pads (terminals) such as an input pad, an output pad, and a power supply pad, and various circuits such as an input/output circuit, a control circuit, and a pixel driving circuit are provided in a region other than the region in which pixels are arranged, in a semiconductor chip used for the line sensor.

A chip layout of a semiconductor chip used for a solid-state image capturing device is disclosed in JP-A-2012-134257.

There are cases in which a degree of freedom in layout of circuits, interconnects, and the like in a semiconductor chip that constitutes the line sensor is limited by the configuration of an optical system used in an image reading device such as a scanner. As a result, the accuracy of output signals from the semiconductor chip and signals transferred inside the semiconductor chip degrades, and there is a risk of not being able to accurately read an image.

An advantage of some aspects of the invention is to provide an image reading device that can, in a line sensor including an optical system that forms an image on a semiconductor chip while reducing the image, read an image with high accuracy as a result of reducing the impedances of interconnects of control signals. Also, an advantage of some aspects of the invention is to provide a semiconductor device that can accurately read an image.

### SUMMARY

These and other advantages can be realized as the following modes or application examples.

### APPLICATION EXAMPLE 1

An image reading device according to the present application example includes: a first image reading chip that reads an image; and an optical unit that forms a reduced image of the image on the first image reading chip. The first image reading chip includes: a first pixel that includes a first photodetector that receives light of a reduced image of the image and performs photoelectric conversion, and generates a first pixel signal; a second pixel that includes a second photodetector that receives light of a reduced image of the image and performs photoelectric conversion, and generates a second pixel signal; a first readout circuit that is electrically connected to the first pixel and outputs a first readout signal based on the first pixel signal; and a second readout circuit that is electrically connected to the second pixel and outputs a second readout signal based on the second pixel signal; and a control circuit that controls operations of the first readout circuit and the second readout circuit. The first image reading chip has a shape including a first side and a second side that is shorter than the first side. The first pixel and the second pixel are provided side by side in a direction in which the first side extends. The first readout circuit, the second readout circuit, and the control circuit are provided side by side in the direction in which the first side extends.

In the image reading device according to the present application example, the first readout circuit, the second readout circuit, the control circuit that controls operations of the first readout circuit and the second readout circuit are provided side by side along the direction in which the first side extends, in the image reading chip. That is, the control signals for controlling the first readout circuit and the second readout circuit that are output from the control circuit need only be provided in the direction in which the first side extends, and unnecessary routing of interconnects or the like is unlikely to occur. Therefore, the impedances of interconnects of the control signals can be reduced, and images can be accurately read.

Also, in the image reading device according to the present application example, the first pixel and the second pixel are provided side by side along the direction in which the first side extends, in the image reading chip. That is, the first pixel signal output from the first pixel is transmitted to the first readout circuit along the second side, and the second pixel signal output from the second pixel is transmitted to the second readout circuit along the second side. That is, the interconnects for transmitting the control signals for controlling the first readout circuit and the second readout circuit and the interconnects for transmitting the first pixel signal and the second pixel signal that are respectively output from the first pixel and the second pixel are not provided in parallel. Accordingly, stray capacitances that are generated between interconnects can be reduced. As a result, the impedances of interconnects of the control signals can be reduced, and images can be accurately read.

### APPLICATION EXAMPLE 2

In the image reading device according to the above-described application example, the first readout circuit includes a first scanning circuit that controls an output timing of the first readout signal, the second readout circuit includes a second scanning circuit that controls an output timing of the second readout signal, after the first photodetector and the second photodetector receive light of an reduced image of the image, the timing at which the first readout signal is output by the first scanning circuit is earlier than the timing at which the second readout signal is output by the second scanning circuit. The distance between the control circuit and the first scanning circuit may be shorter than the distance between the control circuit and the second scanning circuit.

The first scanning circuit and the second scanning circuit may include a shift register.

In the image reading device according to the present application example, the first scanning circuit controls the output timing of the first readout signal, and the second scanning circuit controls the output timing of the second readout signal, in the image reading chip. After the first scanning circuit has operated and output the first readout signal, the second scanning circuit operates and outputs the second readout signal. Furthermore, the first scanning circuit is arranged closer to the control circuit relative to the second scanning circuit. The first scanning circuit included in the first readout circuit and the second scanning circuit included in the second readout circuit operate according to the signals from the control circuit. That is, the first scanning circuit that operates first is arranged closer to the control circuit relative to the second scanning circuit that operates later. Accordingly, it is possible to avoid the interconnects for transmitting the control signal for controlling the first scanning circuit and the second scanning circuit from becoming complicated, and unnecessary interconnects can be reduced. As a result, the impedance of interconnect of the control signal can be reduced, and images can be accurately read.

### APPLICATION EXAMPLE 3

In the image reading device according to the above-described application example, the control circuit may not be provided between the first scanning circuit and the second scanning circuit.

In the image reading device according to the present application example, the control circuit is not provided between the first scanning circuit and the second scanning circuit, in the image reading chip. That is, the control circuit, the first scanning circuit, and the second scanning circuit are arranged in this order in the image reading chip. As a result of being arranged this way, the control signal output from the control circuit can be transmitted in order of arrangement of scanning circuits in terms of closeness to the control circuit, namely in order of the first scanning circuit, the second scanning circuit, and so on. Therefore, the interconnect for transmitting the control signal for controlling the scanning circuit and the second scanning circuit that is output from the control circuit does not become complicated, and the impedance of interconnect of the control signal can further be reduced.

### APPLICATION EXAMPLE 4

In the image reading device according to the above-described application example, the first readout circuit includes a first amplification circuit that amplifies the first pixel signal and generates the first readout signal, and the second readout circuit includes a second amplification circuit that amplifies the second pixel signal and generates the second readout signal. A distance between the second side and the control circuit may be shorter than a distance between the second side and the first amplification circuit, and the distance between the second side and the control circuit may be shorter than a distance between the second side and the second amplification circuit.

In the image reading device according to the present application example, the control circuit is not provided between the first amplification circuit and the second amplification circuit, in the image reading chip.

In the image reading device according to the present application example, the control circuit is provided on the second side side relative to the first amplification circuit and the second amplification circuit, in the image reading chip. That is, the first amplification circuit and the second amplification circuit can be arranged without dividing the circuit blocks thereof, a difference in characteristics between the first amplification circuit and the second amplification circuit including variations in characteristics due to variations in manufacturing the image reading chip can be reduced. As a result, the characteristics of signals are stabilized, and images can be accurately read.

### APPLICATION EXAMPLE 5

In the image reading device according to the above-described application example, the first image reading chip includes a constant voltage terminal to which a constant voltage is supplied. A distance between the constant voltage terminal and the first readout circuit may be shorter than a distance between the constant voltage terminal and the control circuit, and a distance between the constant voltage terminal and the second readout circuit may be shorter than the distance between the constant voltage terminal and the control circuit.

In the image reading device according to the present application example, the constant voltage terminal to which the constant voltage for generating voltages such as the reference voltage to be supplied to the first readout circuit and the second readout circuit is provided on a side separated from the control circuit relative to the first readout circuit and the second readout circuit, in the image reading chip. That is, the interconnects for transmitting voltages for the control circuit to operate and the interconnect for transmitting a control signal input to the control circuit can be separately arranged. Accordingly, the mutual interference between the voltages for the control circuit to operate, the control signal input to the control circuit, and the constant voltage for generating the reference voltage and the like is reduced, and the accuracy of the signals and the voltages can be improved. Accordingly, image reading accuracy can be improved.

### APPLICATION EXAMPLE 6

In the image reading device according to the above-described application example, the first image reading chip includes: a third amplification circuit that amplifies a signal that was output from at least one of the first readout circuit and the second readout circuit, and generates an amplified signal; and an output circuit that generates, based on the amplified signal, an output signal to be output to the outside of the first image reading chip. A distance between the output circuit and the third amplification circuit may be shorter than a distance between the output circuit and the control circuit.

In the image reading device according to the present application example, the third amplification circuit that amplifies signals output from the first readout circuit and the second readout circuit is provided in the vicinity of the output circuit that performs output to the outside of the image reading chip, in the image reading chip. That is, the distance between the third amplification circuit and the output circuit is shorter than the distance between the third amplification circuit and the control circuit. Accordingly, the length of the interconnect in which the signal amplified in the third amplification circuit propagates to the input of the output circuit can be reduced, and impedance of the interconnect can be reduced. Therefore, the accuracy of signal output from the output circuit can be improved.

### APPLICATION EXAMPLE 7

The image reading device according to the above-described application example further includes a second image reading chip. The image includes a first partial image and a second partial image. The optical unit may form a reduced image of the first partial image on the first image reading chip, and form a reduced image of the second partial image on the second image reading chip.

The image reading device according to the present application example includes the first image reading chip and the second image reading chip, and the first image reading chip and the second image reading chip respectively read the first partial image and the second partial image, which are reduced images of portions of the image. That is, the first image reading chip and the second image reading chip each constitute an optical reduction system image reading device, and an image having a deep depth of field can be read. Furthermore, in the image reading device according to the present application example, the image reading device divides one image, and reads divided reduced images using the plurality of image reading chips, and as a result, the image reading device can be realized with a small reduction ratio relative to a known optical reduction system image reading device, and the optical path length for reducing the image can be reduced.

### APPLICATION EXAMPLE 8

A semiconductor device according to the present application example includes: a first pixel that includes a first photodetector that receives light of a reduced image of an image and performs photoelectric conversion, and generates a first pixel signal; a second pixel that includes a second photodetector that receives light of a reduced image of the image and performs photoelectric conversion, and generates a second pixel signal; a first readout circuit that is electrically connected to the first pixel and reads out the first pixel signal; a second readout circuit that is electrically connected to the second pixel and reads out the second pixel signal; a control circuit that controls operations of the first readout circuit and the second readout circuit; a first side; and a second side that is shorter than the first side. The first pixel and the second pixel are provided side by side in a direction in which the first side extends, and the first readout circuit, the second readout circuit, and the control circuit are provided side by side in the direction in which the first side extends.

In the semiconductor device according to the present application example, the first readout circuit, the second readout circuit, and the control circuit that controls the operations of the first readout circuit and the second readout circuit are provided side by side in the direction in which the first side extends. That is, the interconnects of the control signals for controlling the first readout circuit and the second readout circuit that are output from the control circuit need only be provided in the direction in which the first side extends, and unnecessary routing of interconnects or the like is unlikely to occur. As a result, the impedances of interconnects of the control signals can be reduced, and images can be accurately read.

Also, in the semiconductor device according to the present application example, the first pixel and the second pixel are provided side by side along the direction in which the first side extends. That is, the first pixel signal output from the first pixel is transmitted to the first readout circuit along the second side, and the second pixel signal output from the second pixel is transmitted to the second readout circuit along the second side. That is, the interconnects for transmitting the control signals for controlling the first readout circuit and the second readout circuit and the interconnects for transmitting the first pixel signal and the second pixel signal that are respectively output from the first pixel and the second pixel are not provided in parallel. As a result, the stray capacitances that are generated between interconnects can be reduced. Therefore, the impedances of interconnects of the control signals can be reduced, and images can be accurately read.

### BRIEF DESCRIPTION OF THE DRAWINGS

The invention will be described with reference to the accompanying drawings, wherein like numbers reference like elements.

FIG. 1 is an external perspective view of a multifunction peripheral according to a present embodiment.

FIG. 2 is a perspective view of an internal structure of a scanner unit.

FIG. 3 is an exploded perspective view schematically illustrating a configuration of an image sensor module.

FIG. 4 is a plan view schematically illustrating an arrangement of image reading chips.

FIG. 5 is a schematic diagram illustrating a configuration of an optical portion of the image sensor module.

FIG. 6 is a schematic diagram for describing a divided optical reduction system

FIG. 7 is a block diagram illustrating a functional configuration of the scanner unit.

FIG. 8 is a block diagram illustrating a circuit configuration of the image reading chip.

FIG. 9 is a circuit configuration diagram illustrating a configuration of a pixel circuit and a column processing circuit.

FIG. 10 is a timing chart illustrating operation timings of a signal processing circuit.

FIG. 11 is a diagram illustrating a layout configuration of the image reading chip of the present embodiment.

### DESCRIPTION OF EXEMPLARY EMBODIMENTS

Hereinafter, preferred embodiments of the invention will be described in detail with reference to the drawings. The drawings used are provided to facilitate the understanding of the description. Note that the embodiments given below are not intended to unduly limit the scope of the invention recited in the appended claims. In addition, not all of the constituent elements described below are essential to the invention.

A description will be given below of a multifunction peripheral (multifunction peripheral apparatus) 1, to which an image reading device according to the invention is applied, with reference to the accompanying drawings.

1. Outline of Multifunction Peripheral

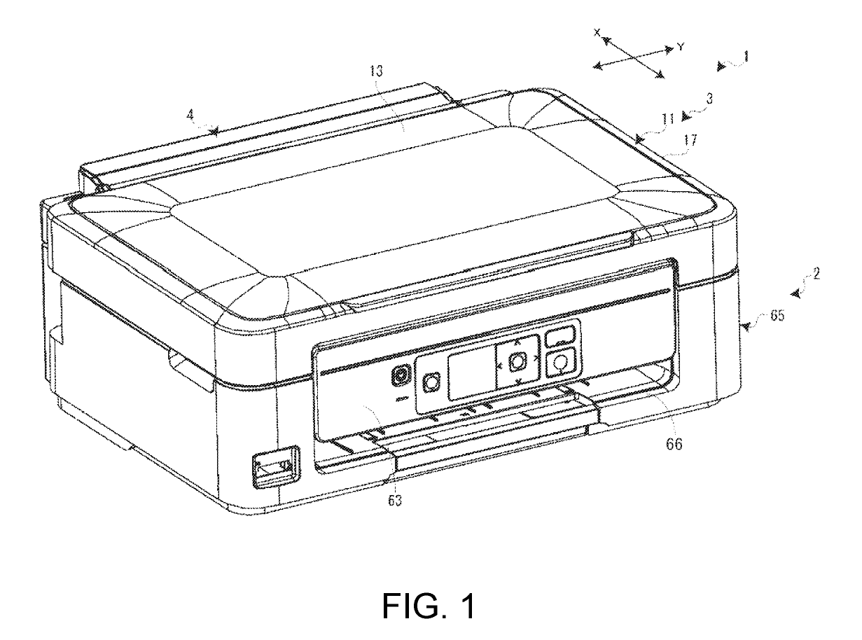

FIG. 1 is an external perspective view illustrating the multifunction peripheral 1. As shown in FIG. 1, the multifunction peripheral 1 integrally includes a printer unit (image recording device) 2 that is a device main body, and a scanner unit (image reading device) 3 that is an upper unit provided on top of the printer unit 2. Note that, in the following description, a front rear direction in FIG. 1 is defined as a main scanning direction X, and a right left direction is defined as a sub scanning direction Y. Also, the main scanning direction X and the sub scanning direction Y are described in the drawings as X and Y that are orthogonal to each other.

As shown in FIG. 1, the printer unit 2 includes: a conveyance portion (not shown) that conveys a sheet of recording medium (print paper or cut sheets) along a feed path; a printing portion (not shown) that is provided above the feed path, and performs inkjet print processing on the recording medium; a panel operation portion 63 provided on a front face; a device frame (not shown) incorporating the conveyance portion, the printing portion, and the operation portion 63; and a device housing 65 that covers the above-described constituent elements. The device housing 65 is provided with a discharge port 66 through which the printed recording medium is discharged. Although not shown in the diagram, a USB port and a power supply port are provided in a lower portion of a rear face. That is, the multifunction peripheral 1 is configured to be connectable to a computer and the like via the USB port.

The scanner unit 3 is pivotably supported by the printer unit 2 via a hinge 4 provided at a rear end, and covers a top portion of the printer unit 2 so as to be capable of opening and closing. That is, by raising the scanner unit 3 in the pivotal direction, an upper surface opening of the printer unit 2 is exposed so as to expose the inside of the printer unit 2 via the upper surface opening. On the other hand, by lowering the scanner unit 3 in the pivotal direction to place it on the printer unit 2, the upper surface opening is closed by the scanner unit 3. The configuration in which the scanner unit 3 can be opened in the manner as described above allows ink cartridge exchange, the clearance of paper jams, and the like to be performed.

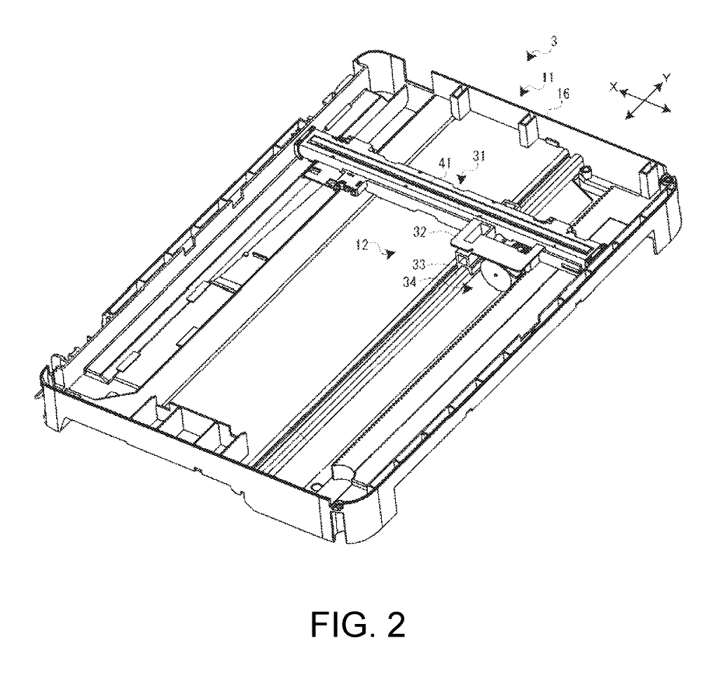

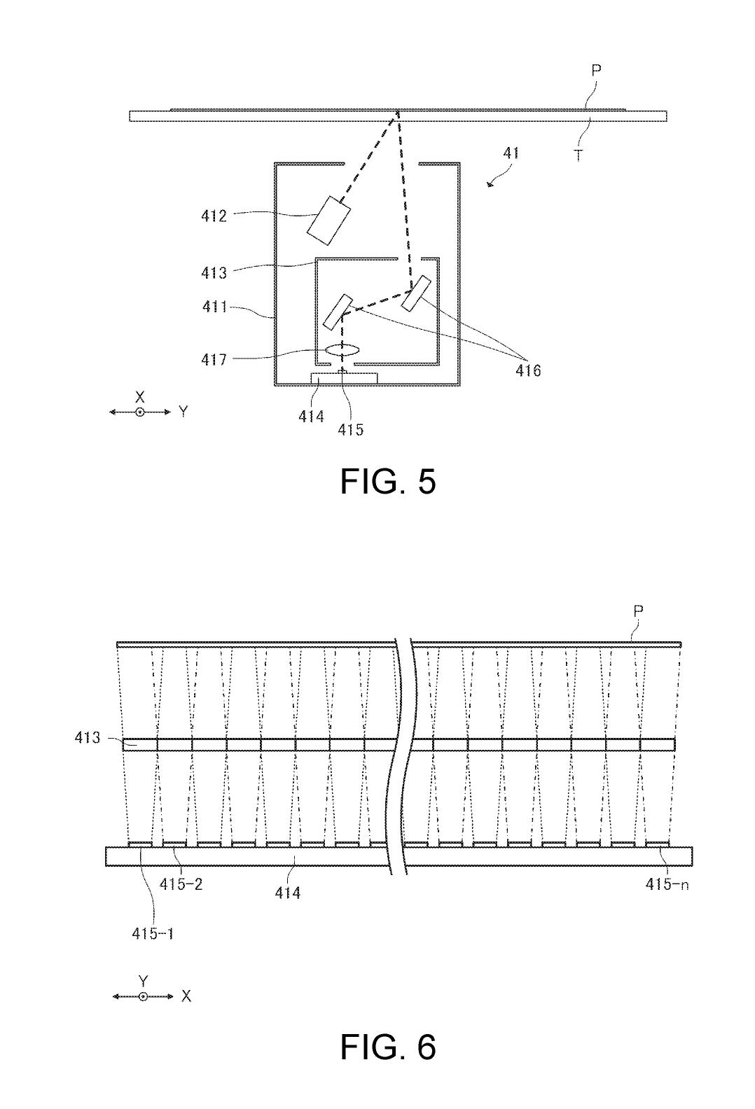

FIG. 2 is a perspective view of an internal structure of the scanner unit 3. As shown in FIGS. 1 and 2, the scanner unit 3 includes an upper frame 11 that is a casing, an image reading portion 12 housed in the upper frame 11, and an upper cover 13 that is pivotably supported on top of the upper frame 11. The upper frame 11 includes a box-shaped lower case 16 that houses the image reading portion 12 and an upper case 17 that covers the top side of the lower case 16. A document placing plate (platen T: refer to FIG. 5) made of glass is provided over the upper case 17, and a medium to be read (document P: refer to FIG. 5) is placed on the document placing plate with the side to be read facing downward. On the other hand, the lower case 16 is formed to have a shallow box shape with its upper side being open.

As shown in FIG. 2, the image reading portion 12 includes a line sensor type sensor unit 31, a sensor carriage 32 incorporating the sensor unit 31, a guide shaft 33 that extends in the sub scanning direction Y and slidably supports the sensor carriage 32, and a self-propelled sensor moving mechanism 34 that moves the sensor carriage 32 along the guide shaft 33. The sensor unit 31 includes an image sensor module 41 that is constituted by a CMOS (complementary metal-oxide-semiconductor) line sensor extending in the main scanning direction X, and is moved back and forth along the guide shaft 33 in the sub scanning direction Y by the motor-driven sensor moving mechanism 34. Accordingly, the image on the medium to be read placed on the document placing plate is read. The sensor unit 31 may be constituted by a CCD (charge coupled device) line sensor.

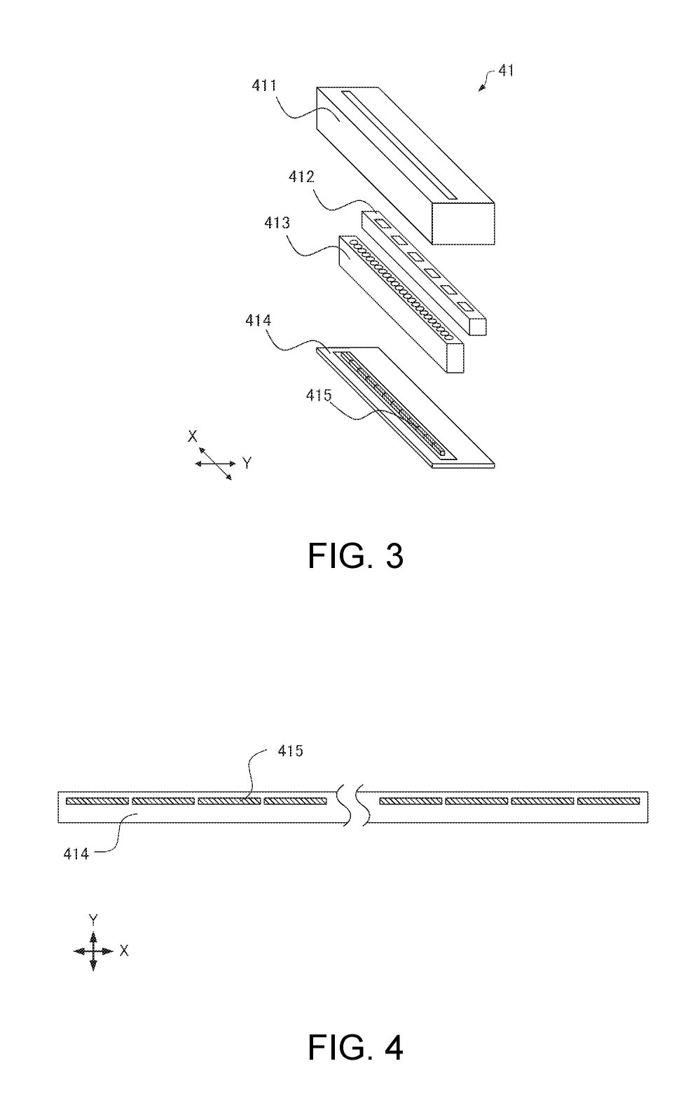

FIG. 3 is an exploded perspective view schematically illustrating a configuration of the image sensor module 41. In the example shown in FIG. 3, the image sensor module 41 includes a case 411, a light source 412, an optical portion 413, module substrate 414, and an image reading chip 415 (semiconductor device) for reading an image. The light source 412, the optical portion 413, and the image reading chip 415 are housed between the case 411 and the module substrate 414. The case 411 is provided with a slit. The light source 412 emits light to a medium to be read. The light emitted by the light source 412 is incident on the medium to be read via the slit, and the light reflected from the medium to be read is input into the optical portion 413 via the slit. The optical portion 413 guides the input light to the image reading chips 415 so as to form a reduced image thereon.

FIG. 4 is a plan view schematically showing an arrangement of the image reading chip 415. As shown in FIG. 4, a plurality of image reading chips 415 are arranged side by side on the module substrate 414 in a unidimensional direction (the main scanning direction X in FIG. 4). Each image reading chip 415 includes a large number of photodetectors that are arranged in a line. The more densely the photodetectors are provided in each image reading chip 415, the higher image reading resolution of the scanner unit 3 (image reading device) can be achieved. Also, by providing a greater number of image reading chips 415, it is possible to realize a scanner unit 3 (image reading device) that can read a large image as well.

The image sensor module 41 and the optical portion 413 in the present embodiment will be described in detail using FIGS. 5 and 6.

FIG. 5 is a diagram illustrating an example of an optical path inside the image sensor module 41 in the present embodiment, and shows a state in which the line of sight is parallel to the main scanning direction X (cross-sectional view along the sub scanning direction Y). Note that broken lines in FIG. 5 show an example of the optical path of light emitted from the light source 412.

The optical portion 413 includes a plurality of reflecting mirrors 416 and a lens 417.

The light source 412 emits light to a document P. The lens 417 forms an image on the image reading chip 415 with light from the document P. The reflecting mirrors 416 are for increasing the length of the optical path of the reflected light in order for the lens 417 to form an image on the image reading chip 415 with light reflected from the document P. When the optical path cannot be increased, the angle of view increases. The image reading chip 415 outputs a signal according to the received light. Note that the arrangement and number of the reflecting mirrors 416 and the lens 417 in the optical portion 413 described in FIG. 5 are an example, and may be optimized according to the optical path and reduction ratio.

Also, FIG. 6 is a diagram illustrating an exemplary optical path inside the image sensor module 41 in the present embodiment, and shows a state in which the line of sight is parallel to the sub scanning direction Y (cross-sectional view along the main scanning direction X). Note that, in FIG. 6, the range of the optical path of light reflected from the document P that each of the image reading chips 415 (415-1 to 415-n) can receive is illustrated by adjacent broken lines or one dot chain lines.

In FIG. 6, the light reflected from the document P is guided to the image reading chips 415 via the optical portion 413. As described above, the plurality of image reading chips 415 (415-1 to 415-n) are arranged side by side in the main scanning direction X. Also, images of successive portions, in the main scanning direction X, of the document P are formed on the respective plurality of image reading chips 415 (415-1 to 415-n) while the images are partially overlapped and reduced by the optical portion 413.

That is, an image of a portion (example of “first partial image”) of the document P (example of “image”), the image being reduced by the optical portion 413 (example of “optical unit”), is formed on the image reading chip 415-1 (example of “first image reading chip”). Also, an image of another portion (example of “second partial image”) of the document P, the image being reduced by the optical portion 413, is formed on the image reading chip 415-2 (example of “second image reading chip”).

A reduced image of a portion of the document P is formed on each image reading chip 415 in the present embodiment via the optical portion 413. Therefore, photodetectors provided in the image reading chip 415 need not be arranged up to an end of the image reading chip 415. As a result, in the image reading chip 415 in the present embodiment, circuits can be arranged with less limitation due to the resolution and the number of pixels, and the space can be effectively utilized.

The image sensor module 41 in the present embodiment is realized by a so-called optical reduction system image reading method in which light from the light source 412 is emitted onto the document P, and an image is formed on the image reading chips 415 while the optical path length of the light reflected by the document P is secured and the image is reduced by the reflecting mirrors 416 and the lens 417 provided in the optical portion 413. That is, a large depth of field can be realized compared with an image reading device of a CIS (Contact Image Sensor) method. Also, since a plurality of image reading chips 415 are used, the reduction ratio of an image formed on each image reading chip 415 can be reduced relative to the image reading device of a known optical reduction system. Therefore, the optical path of light reflected from the document P can be reduced, and the size of the image sensor module 41 can be reduced. Note that the scanner unit 3 according to the present embodiment uses an image reading method in which data of a plurality of divided images generated by one image (document) being divided and reduced is acquired by the plurality of image reading chips 415 (415-1 to 415-n), image processing is performed based on the data acquired by the plurality of image reading chips 415 (415-1 to 415-n), and as a result the one image (document) is restored, which is referred to as a divided optical reduction system.

2. Functional Configuration of Image Reading Device

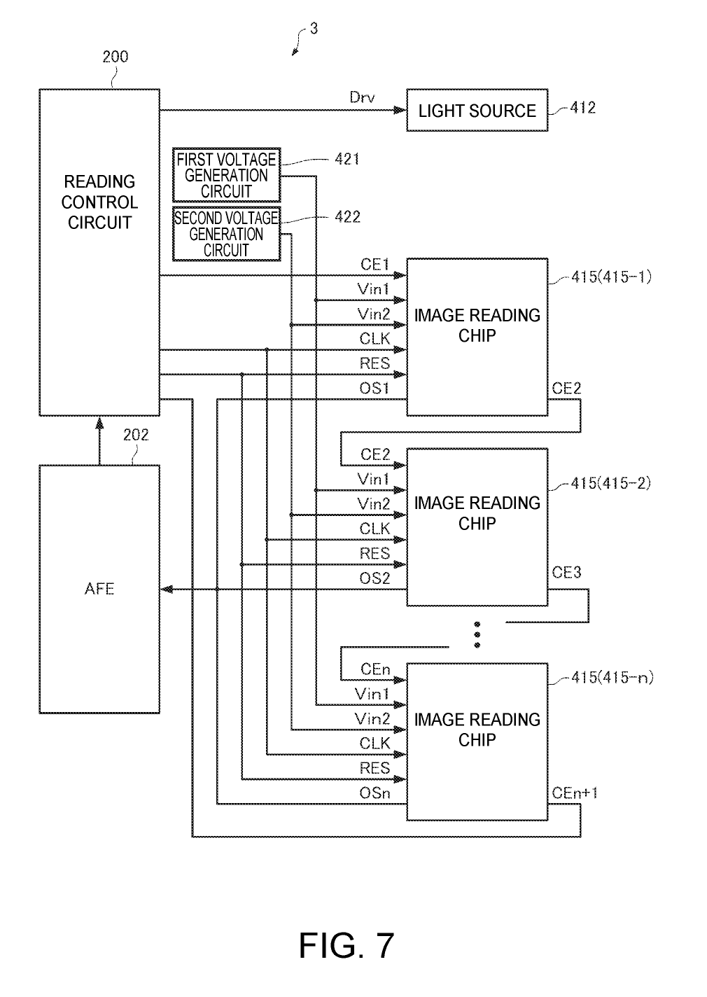

FIG. 7 is a diagram illustrating a functional configuration of the scanner unit 3. In the example shown in FIG. 7, the scanner unit 3 includes a reading control circuit 200, an analog front end (AFE) 202, the light source 412, the plurality of image reading chips 415 (415-1 to 415-n), a first voltage generation circuit 421, and a second voltage generation circuit 422. Also, the reading control circuit 200, the analog front end (AFE) 202, the first voltage generation circuit 421, and the second voltage generation circuit 422 may be provided in the module substrate 414 or in an unshown substrate that is different from the module substrate 414. Also, the reading control circuit 200, the analog front end (AFE) 202, the first voltage generation circuit 421, and the second voltage generation circuit 422 may each be realized by an integrated circuit (IC).

The reading control circuit 200 supplies a drive signal Drv in a fixed time period of exposure time Δt in each of a read period t of an image, so as to cause the light source 412 to emit light.

Also, the reading control circuit 200 supplies a clock signal CLK and a resolution setting signal RES to the plurality of image reading chips 415 in common. The clock signal CLK is an operation clock signal for the image reading chips 415, and the resolution setting signal RES is a signal for setting a resolution in reading an image by the scanner unit 3. The resolution setting signal RES may be a 2-bit signal, which causes the resolution of 1200 dpi to be set when “00”, 600 dpi to be set when “01”, and 300 dpi to be set when “01”, for example.

The light source 412 emits light according to the drive signal Drv output from the reading control circuit 200. The light source 412 uses a white light source, and the white light source may include a single color light source and an unshown filter or the like, or may be constituted by a red, green, and blue light sources.

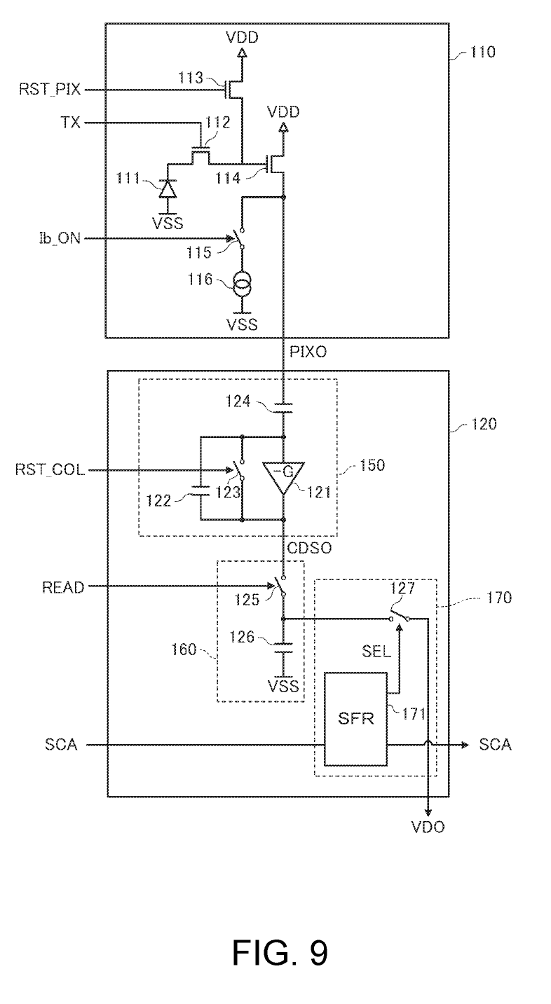

N chips of the image reading chips 415 (415-1 to 415-n) are arranged side by side on the module substrate 414. The image reading chips 415 operate in synchronization with the clock signal CLK when respective chip enable signals CEi (i=1 to n) are activated (high level, in the present embodiment). The image reading chips 415 (415-1 to 415-n) each detect light that was emitted by the light source 412 and reflected by a medium to be read using photodetectors 111 (refer to FIG. 9), and convert the detected light to an electric signal. Then, the image reading chips 415 (415-1 to 415-n) respectively generate and output image signals OSi (i=1 to n) including image information based on the resolution set by the resolution setting signal RES.

The first voltage generation circuit 421 and the second voltage generation circuit 422 supply power for the image reading chips 415 (415-1 to 415-n) to operate.

The analog front end (AFE) 202 receives the image signals OSi (i=1 to n) that are respectively output by the plurality of image reading chips 415 (415-1 to 415-n), performs amplification processing and A/D conversion processing on the received image signals OSi (i=1 to n), and converts the received image signals to digital signals each including a digital value according to the amount of light received by a photodetector 111. Then, the analog front end (AFE) 202 sequentially transmits the digital signals to the reading control circuit 200.

The reading control circuit 200 receives the digital signals sequentially transmitted from the analog front end (AFE) 202, and generates read image information of the image sensor module 41.

3. Configuration and Operation of Image Reading Chip

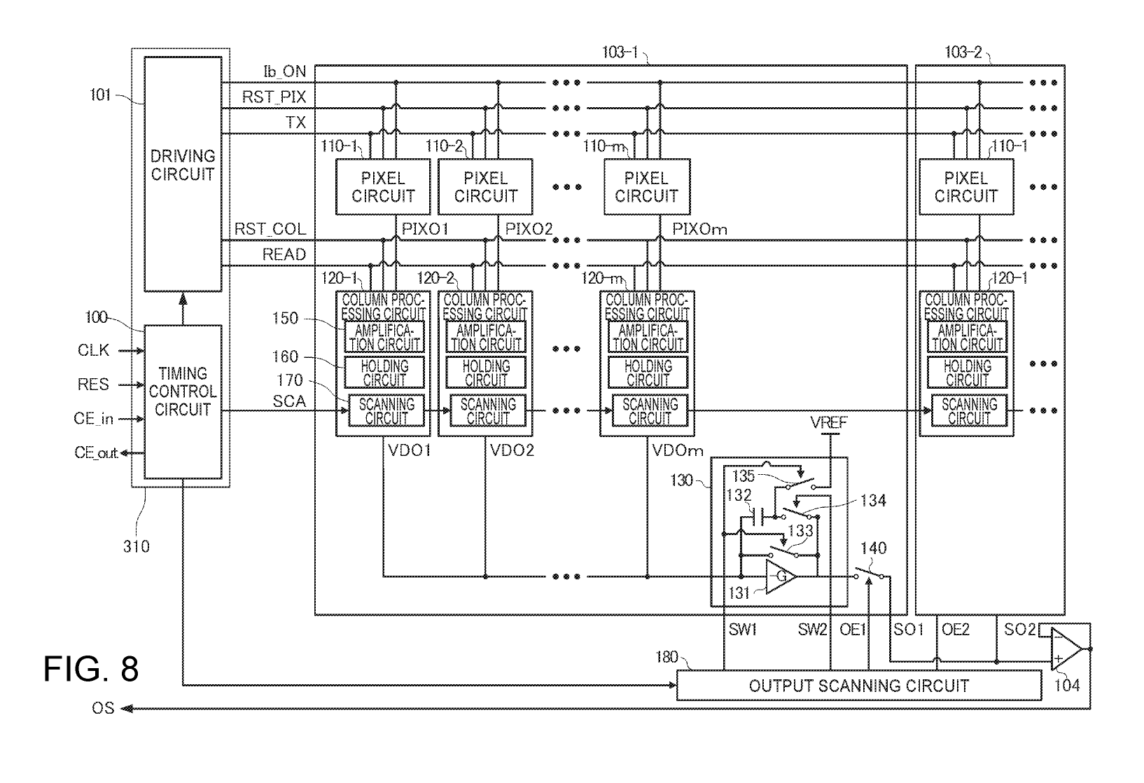

The configuration and operation of the image reading chips 415 in the present embodiment will be described using FIGS. 8 to 10. Note that because the plurality of image reading chips 415 (415-1 to 415-n) that constitute the image sensor module 41 all have the same configuration, each image reading chip 415 will be described as an image reading chip 415. Also, the chip enable signals CEi (i=1 to n) respectively input to the image reading chips 415-i (i=1 to n) will each be described as a chip enable signal CE_in, and chip enable signals CEi+1 (i=1 to n) that are respectively output from the image reading chips 415-i (i=1 to n) will each be described as a chip enable signal CE_out. Also, image signals OSi (i=1 to n) respectively output from the image reading chips 415-i (i=1 to n) will each be described as an image signal OS.

FIG. 8 is a diagram illustrating a circuit configuration of the image reading chip 415. The image reading chip 415 shown in FIG. 8 includes a drive control circuit 310, two signal processing circuits 103-1 and 103-2, an operational amplifier 104, and an output scanning circuit 180. These circuits are supplied with a first voltage Vin1, a second voltage Vin2, and the ground potential that are input to unshown terminals of the image reading chip 415 so as to operate.

The drive control circuit 310 includes a timing control circuit 100 and a driving circuit 101.

The timing control circuit 100 includes an unshown counter that counts pulses of the clock signal CLK, and generates a control signal for controlling the operation of the driving circuit 101, a control signal for controlling the operation of the output scanning circuit 180, and a scan signal SCA for controlling the operations of a later-described scanning circuit 170 based on an output value (count value) of the counter.

Also, the timing control circuit 100, upon receiving an active chip enable signal CE_in, activates the operation of the image reading chip 415. Also, the timing control circuit 100, after completing the processing of the image reading chip 415 and outputting an active chip enable signal CE_out to the next image reading chip 415 or the reading control circuit 200 (refer to FIG. 7), deactivates the operation of the image reading chip 415.

The driving circuit 101 generates a bias current ON signal lb_ON, in synchronization with the clock signal CLK, that is activated (high level, in the present embodiment) during a fixed time period at a predetermined timing based on the control signal from the timing control circuit 100. This bias current ON signal lb_ON is supplied, in common, tom pixel circuits 110 (110-1 to 110-m) included in each of the two signal processing circuits 103-1 and 103-2.

Also, the driving circuit 101 generates a pixel reset signal RST_PIX and a column reset signal RST_COL, in synchronization with the clock signal CLK, that is activated (high level, in the present embodiment) during a fixed time period at a predetermined timing based on the control signal from the timing control circuit 100. This pixel reset signal RST_PIX is supplied, in common, to them pixel circuits 110 (110-1 to 110-m) included in each of the two signal processing circuits 103-1 and 103-2. Also, the column reset signal RST_COL is supplied, in common, to m column processing circuits 120 (120-1 to 120-m) included in each of the two signal processing circuits 103-1 and 103-2.

Also, the driving circuit 101 generates a transfer signal TX and a readout signal READ, in synchronization with the clock signal CLK, that is activated (high level, in the present embodiment) during a fixed time period at a predetermined timing based on the control signal from the timing control circuit 100. The transfer signal TX is supplied, in common, to the m pixel circuits 110 (110-1 to 110-m) included in each of the two signal processing circuits 103-1 and 103-2. Also, the readout signal READ is supplied, in common, to the m column processing circuits 120 (120-1 to 120-m) included in each of the two signal processing circuits 103-1 and 103-2.

The two signal processing circuits 103-1 and 103-2 have the same configuration, and each include the m pixel circuits 110 (110-1 to 110-m), the m column processing circuits 120 (120-1 to 120-m), an amplification circuit 130, and a switch 140.

The m pixel circuits 110 (110-1 to 110-m) respectively output pixel signals PIXO1 to PIXOm each having a voltage corresponding to the amount of light received from a medium to be read during a period of exposure time Δt, due to light emitted by the light source 412.

For example, the pixel circuit 110-1 includes a photodetector 111 (refer to FIG. 9) (example of “first photodetector”) that performs photoelectric conversion on the received light with which an image reduced by the optical portion 413 is formed, and generates a pixel signal PIXO1 (example of “first pixel signal”). The pixel circuit 110-2 includes a photodetector 111 (refer to FIG. 9) (example of “second photodetector”) that performs photoelectric conversion on the received light with which an image reduced by the optical portion 413 is formed, and generates a pixel signal PIXO2 (example of “second pixel signal”).

The m column processing circuits 120 (120-1 to 120-m) each include an amplification circuit 150, a holding circuit 160, and a scanning circuit 170.

The m column processing circuits 120 (120-1 to 120-m) respectively amplify the pixel signals PIXO1 to PIXOm output from the m pixel circuits 110 (110-1 to 110-m) using the respective amplification circuits 150, and each store the amplified voltage in the holding circuit 160 according to the readout signal READ. Then, the column processing circuits 120 (120-1 to 120-m) sequentially output respective image signals VDO1 to VDOm based on the voltage stored in the respective holding circuits 160 to the amplification circuit 130 based on the scan signal SCA input to the scanning circuit 170.

That is, the column processing circuit 120-1 (example of “first readout circuit”) is electrically connected to the pixel circuit 110-1, and reads out the pixel signal PIXO1 from the pixel circuit 110-1. The amplification circuit 150 (example of “first amplification circuit”) included in the column processing circuit 120-1 amplifies the pixel signal PIXO1. The scanning circuit 170 (example of “first scanning circuit”) included in the column processing circuit 120-1 controls the output timing of the image signal VDO1 (example of “first readout signal”) that is generated by the pixel signal PIXO1 being amplified by the amplification circuit 150.

Also, the column processing circuit 120-2 (example of “second readout circuit”) is electrically connected to the pixel circuit 110-2, and reads out the pixel signal PIXO2 from the pixel circuit 110-2. The amplification circuit 150 (example of “second amplification circuit”) included in the column processing circuit 120-2 amplifies the pixel signal PIXO2. The scanning circuit 170 (example of “second scanning circuit”) included in the column processing circuit 120-2 controls the output timing of the image signal VDO2 (example of “second readout signal”) that is generated by the pixel signal PIXO2 being amplified by the amplification circuit 150.

Here, in the present embodiment, the scanning circuits 170 respectively included in the m column processing circuits 120 (120-1 to 120-m) sequentially operate according to the scan signal SCA input from the timing control circuit 100. Specifically, each scanning circuit 170 includes a shift register, for example. For example, when the scan signal SCA is input to the scanning circuit 170 included in the column processing circuit 120-j (j=1 to m−1), the column processing circuit 120-j (j=1 to m−1) outputs the image signal VDOj (j=1 to m−1) to the amplification circuit 130, and outputs the scan signal SCA to the column processing circuit 120-j+1 (j=1 to m−1). The scan signal SCA is input to the scanning circuit 170 included in the column processing circuit 120-j+1 (j=1 to m−1), and the column processing circuit 120-j+1 (j=1 to m−1) outputs the image signal VDOj+1 (j=1 to m−1) to the amplification circuit 130.

In the present embodiment, the scan signal SCA is input such that the timing at which the image signal VDO1 is output by the scanning circuit 170 included in the column processing circuit 120-1 is earlier than the timing at which the image signal VDO2 is output by the scanning circuit 170 included in the column processing circuit 120-2.

The amplification circuit 130 (example of “third amplification circuit”) amplifies at least one of the image signal VDO1 output from the column processing circuit 120-1 (example of “first readout circuit”) and the image signal VDO2 output from the column processing circuit 120-2 (example of “second readout circuit”), and generates the image signal SO1 (example of “amplified signal”).

The amplification circuit 130 includes an operational amplifier 131, a capacitor 132, and switches 133 to 135.

The operational amplifier 131 is a grounded source amplifier constituted by a plurality of MOS transistors, for example. The capacitor 132 is a feedback capacitor of the operational amplifier 131. The switch 133 is a feedback switch of the operational amplifier 131. The switch 134 is a feedback signal control switch of the operational amplifier 131. The switch 135 is an external input signal control switch of the operational amplifier 131.

One end of the switch 133 and one end of the capacitor 132 is connected to an input terminal of the operational amplifier 131. The other end of the capacitor 132 is connected to one end of the switch 134 and one end of the switch 135.

The other end of the switch 133 and the other end of the switch 134 are connected to an output terminal of the operational amplifier 131. A reference voltage VREF is applied to the other end of the switch 135. The reference voltage VREF may be generated by a voltage generator that is not shown in FIG. 8, or may be supplied from an external terminal of the image reading chip 415.

A switch control signal SW1 from the output scanning circuit 180 is commonly input to a control terminal of the switch 133 and a control terminal of the switch 135, and the switches 133 and 135 are turned on when the switch control signal SW1 is activated (high level, in the present embodiment). Also, a switch control signal SW2 from the output scanning circuit 180 is input to a control terminal of the switch 134, and the switch 134 is turned on when the switch control signal SW2 is activated (high level, in the present embodiment). The switch control signal SW1 and the switch control signal SW2 are exclusively activated (high level, in the present embodiment).

Output enable signals OE1 and OE2 from the output scanning circuit 180 are respectively input to control terminals of the switches 140 respectively included in the two signal processing circuits 103-1 and 103-2. The switches 140 included in the two signal processing circuits 103-1 and 103-2 are respectively turned on when the respective output enable signals OE1 and OE2 are activated (high level, in the present embodiment).

The output enable signals OE1 and OE2 are signals only one of which is sequentially activated (high level), and the two signal processing circuits 103-1 and 103-2 sequentially output image signals SO1 and SO2 from the amplification circuits 130 via the switches 140, respectively.

The operational amplifier 104 (example of “output circuit”) generates an image signal OS (example of “output signal”) to be output to the outside of the image reading chip 415-1 (example of “first image reading chip”).

Output terminals (other ends of respective switches 140) of the two signal processing circuits 103-1 and 103-2 are commonly connected to a non-inverting input terminal of the operational amplifier 104, and an inverting input terminal is connected to an output terminal thereof. This operational amplifier 104 is configured as a voltage follower, and the output voltage matches the voltage at the non-inverting input terminal. Accordingly, the output signal of the operational amplifier 104 is a signal that sequentially includes the image signals SO1 and SO2, and is output as an image signal OS from the image reading chip 415.

As described above, the drive control circuit 310 (example of “control circuit”) controls the operations of the m column processing circuits 120 (120-1 to 120-m) including the column processing circuits 120-1 and 120-2.

Also, the m pixel circuits 110 (110-1 to 110-m) shown in FIG. 8 all have the same configuration. Similarly, the m column processing circuits 120 (120-1 to 120-m) all have the same configuration. Therefore, each of the m pixel circuits 110 (110-1 to 110-m) will be described in detail as a pixel circuit 110, and each of them column processing circuits 120 (120-1 to 120-m) will be described in detail as a column processing circuit 120, using FIG. 9.

FIG. 9 is a diagram illustrating a circuit configuration of the pixel circuit 110 and the column processing circuit 120. As shown in FIG. 9, the pixel circuit 110 includes the photodetector 111, NMOS transistors 112 to 114, a switch 115, and a constant current source 116.

The photodetector 111 converts (photoelectric conversion) the received light (light from an image formed in the medium to be read, in the present embodiment) to an electric signal. In the present embodiment, the photodetector 111 is constituted by a photodiode whose anode is supplied with a ground potential VSS and whose cathode is connected to a source terminal of the NMOS transistor 112.

The transfer signal TX is input to a gate terminal of the NMOS transistor 112, and a drain terminal of the NMOS transistor 112 is connected to a gate terminal of the NMOS transistor 114.

The NMOS transistor 113 has a drain terminal supplied with a power supply potential VDD, a gate terminal to which the pixel reset signal RST_PIX is input, and a source terminal connected to the gate terminal of the NMOS transistor 114.

A drain terminal of the NMOS transistor 114 is supplied with the power supply potential VDD, and a source terminal of the NMOS transistor 114 is connected to one end of the switch 115.

The other end of the switch 115 is connected to one end of the constant current source 116, the other end of the constant current source 116 is supplied with the ground potential VSS. Also, the bias current ON signal lb_ON is input to a control terminal of the switch 115. The switch 115 is a switch having a function of controlling a load current for driving the NMOS transistor 114, and turns on when the bias current ON signal lb_ON is activated (high level, in the present embodiment), and as a result, the source terminal of the NMOS transistor 114 is electrically connected to the one end of the constant current source 116. The signal output from the source terminal of the NMOS transistor 114 is input to the column processing circuit 120 as the pixel signal PIXO (one of PIXO1 to PIXOn in FIG. 8).

The column processing circuit 120 includes the amplification circuit 150, the holding circuit 160, and the scanning circuit 170.

The amplification circuit 150 includes an operational amplifier 121, a capacitor 122, a switch 123, and a capacitor 124.

The capacitor 124 has one end connected to the source terminal (output terminal of the pixel circuit 110) of the NMOS transistor 114 in the pixel circuit 110, and the other end is connected to an input terminal of the operational amplifier 121.

The operational amplifier 121 is a grounded source amplifier constituted by a plurality of MOS transistors, for example. The capacitor 122 is a feedback capacitor of the operational amplifier 121. The switch 123 is a feedback switch of the operational amplifier 121. One end of the capacitor 122 and one end of the switch 123 are connected to the input terminal of the operational amplifier 121, and the other end of the capacitor 122 and the other end of the switch 123 are connected to an output terminal of the operational amplifier 121.

The column reset signal RST_COL is input to a control terminal of the switch 123, and the switch 123 is turned on when the column reset signal RST_COL is activated (high level, in the present embodiment).

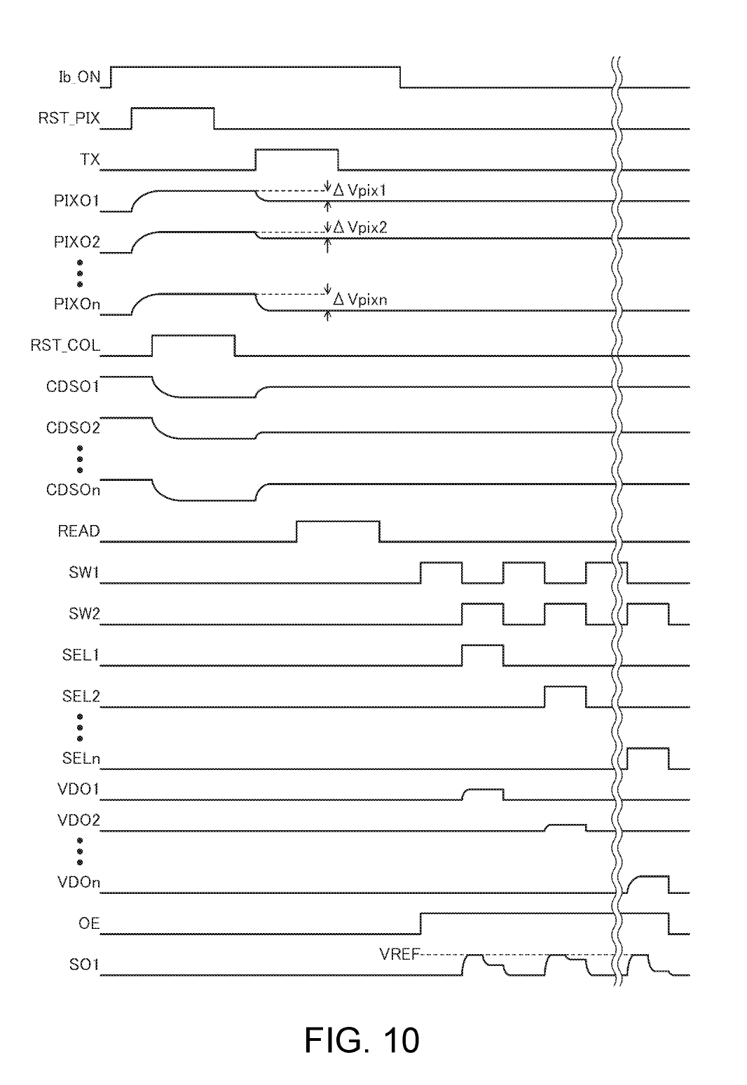

That is, a CDS (Correlated Double Sampling) circuit is configured by the operational amplifier 121, the capacitor 122, the switch 123, and the capacitor 124, in the amplification circuit 150. The amplification circuit 150 has a function of cancelling noise in an output voltage delta Vpix (refer to FIG. 10) from the pixel circuit 110 using the capacitor 124 and performing amplification thereon. The voltage at the output terminal of the operational amplifier 121 is an output signal CDSO of the amplification circuit 150.

The holding circuit 160 includes a switch 125 and a capacitor 126.

One end of the switch 125 is connected to the output terminal (output terminal of the amplification circuit 150) of the operational amplifier 121 included in the amplification circuit 150. The other end of the switch 125 is connected to one end of the capacitor 126. The other end of the capacitor 126 is supplied with the ground potential VSS. The readout signal READ is input to a control terminal of the switch 125, and the switch 125 is turned on when the readout signal READ is activated (high level, in the present embodiment), and as a result, the output terminal of the operational amplifier 121 is electrically connected to the one end of the capacitor 126. Accordingly, charges corresponding to the potential difference between the output signal CDSO of the amplification circuit 150 and the ground potential VSS are accumulated (held) in the capacitor 126.

The scanning circuit 170 includes a switch 127 and a shift register (SFR) 171.

One end of the switch 127 is connected to the one end of the capacitor 126 included in the holding circuit 160, and the other end of the switch 127 is connected to the operational amplifier 131 (input terminal of the amplification circuit 130) included in the amplification circuit 130 (refer to FIG. 8). Also, a selection signal SEL is input to a control terminal of the switch 127. The switch 127 is a column selection switch, is turned on when the selection signal SEL is activated (high level, in the present embodiment), and as a result, the one end of the capacitor 126 is electrically connected to the input terminal (input terminal of the amplification circuit 130) of the operational amplifier 131. A signal (signal having a voltage corresponding to the charges accumulated in the capacitor 126) at the one end of the capacitor 126 is input to the amplification circuit 130 as an image signal VDO (one of VDO1 to VDOm in FIG. 8).

The shift register 171 outputs a selection signal SEL for controlling the switch 127 based on the input scan signal SCA. Then, the shift register 171 transfers the scan signal SCA to the adjacent scanning circuit 170 included in the column processing circuit 120-i+1 (i=1 to m−1).

That is, the scanning circuits 170 sequentially output, based on the respective scan signals SCA, the signals (signals each having a voltage corresponding to the charges accumulated in the capacitor 126) held in the respective holding circuits 160 in the column processing circuits 120-1 to 120-m to the amplification circuit 130.

FIG. 10 is a timing chart illustrating operation timings of the signal processing circuit 103-1 shown in FIG. 8. Note that charges (negative charges) corresponding to the amount of received light are assumed to be accumulated in the photodetector 111 included in each of them pixel circuits 110 (110-1 to 110-m).

As shown in FIG. 10, first, the bias current ON signal lb_ON is activated (high level, in the present embodiment), and the switch 115 is turned on in each of them pixel circuits 110. When the pixel reset signal RST_PIX is activated (high level, in the present embodiment) in this state, the NMOS transistor 113 is turned on, and the power supply potential VDD is supplied to the gate terminal of the NMOS transistor 114, in each of the m pixel circuits 110. Accordingly, the NMOS transistor 114 is turned on, and the voltages of the pixel signals PIXO1 to PIXOm that are respectively output from the m pixel circuits 110 increase to the power supply potential VDD. At this time, because the column reset signal RST_COL is activated (high level), the switch 123 is turned on, and the charges accumulated in the capacitor 122 are discharged (the capacitor 122 is reset), in each of them column processing circuits 120, and the voltages of the output signals CDSO1 to CDSOm of the m amplification circuits 150 decrease to a predetermined voltage.

Next, after the pixel reset signal RST_PIX and the column reset signal RST_COL are deactivated (low level), the transfer signal TX is activated (high level), and therefore, in each of them pixel circuits 110, the NMOS transistor 112 is turned on, and the voltage corresponding to the charges accumulated in the photodetector 111 is applied to the gate terminal of the NMOS transistor 114. The larger the amount of light received by each photodetector 111, the larger the amount of charges (negative charges) accumulated in the photodetector 111, and therefore the voltage of the corresponding gate terminal of the NMOS transistor 114 decreases. Accordingly, the voltages of the pixel signals PIXO1 to PIXOm respectively decrease by ΔVpix1 to ΔVpixm. At this time, since the switch 123 is turned off, the m amplification circuits 150 operate, and the output signals CDSO1 to CDSOm increase in proportion to ΔVpix1 to ΔVpixm, respectively.

Next, after the voltages of the output signals CDSO1 to CDSOm of the m amplification circuits 150 are stabilized, when the readout signal READ is activated (high level, in the present embodiment), the switches 125 are turned on, and charges accumulated in the m capacitors 126 change according to ΔVpix1 to ΔVpixm, respectively.

Next, after the bias current ON signal lb_ON, the transfer signal TX, and the readout signal READ are deactivated (low level, in present embodiment), an output enable signal OE (OE1 or OE2 in FIG. 8) is activated (high level, in the present embodiment) for a fixed period of time. Also, while the output enable signal OE is activated (high level, in the present embodiment), a state in which the switch control signal SW1 is activated (high level, in the present embodiment) and the switch control signal SW2 is deactivated (low level, in present embodiment) and a state in which the switch control signal SW1 is deactivated (low level) and the switch control signal SW2 is activated (high level, in the present embodiment) are alternatingly repeated. Also, every time the switch control signal SW1 is deactivated (low level, in present embodiment) and the switch control signal SW2 is activated (high level, in the present embodiment), m selection signals SEL (SEL1 to SELm), which are respectively controlled by the scanning circuits 170 provided in the m column processing circuits 120 (120-1 to 120-m), are sequentially activated (high level, in the present embodiment).

Then, every time the m selection signals SEL (SEL1 to SELm) are sequentially activated (high level, in the present embodiment), the image signals VDO1 to VDOm respectively having voltages corresponding to the charges accumulated in the capacitors 126 are sequentially output from the m column processing circuits 120 (120-1 to 120-m). The image signals VDO1 to VDOm are sequentially amplified by the amplification circuit 130, and as a result, the image signal SO1 is generated.

The timing chart illustrating the operation timings of the signal processing circuit 103-2 shown in FIG. 8 is similar to those shown in FIG. 10, and therefore the illustration and description thereof are omitted.

4. Circuit Layout of Image Reading Chip

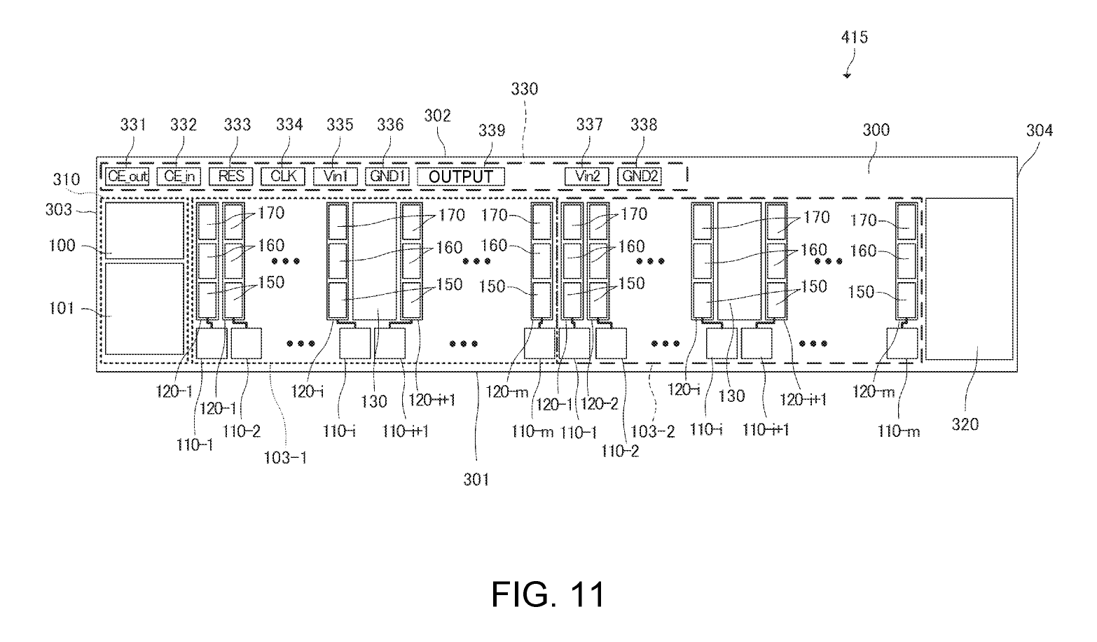

FIG. 11 is a diagram schematically illustrating a circuit layout of the image reading chip 415 in the present embodiment.

The image reading chip 415 is formed on a silicon substrate 300 having a substantially rectangular shape, which is constituted by a long side 301 (example of “first side”), a long side 302, a short side 303 (example of “second side”) that is shorter than the long side 301, and a short side 304.

The image reading chip 415 includes the two signal processing circuits 103-1 and 103-2, the drive control circuit 310, a reference voltage generation circuit 320, and an input/output portion 330. Note that the constituent elements included in the image reading chip 415 described above are electrically connected by unshown interconnects. In the present embodiment, the circuits that constitute the image reading chip 415 are integrally formed on the silicon substrate 300 using semiconductor processing including photolithography. That is, the image reading chip 415 is configured as one IC (Integrated Circuit) chip.

The two signal processing circuits 103-1 and 103-2 are provided adjacent to each other along the long side 301, the signal processing circuit 103-1 is formed on the short side 303 side, and the signal processing circuit 103-2 is formed on the short side 304 side.

Each of the two signal processing circuits 103-1 and 103-2 includes them pixel circuits 110 (110-1 to 110-m), them column processing circuits 120 (120-1 to 120-m), and the amplification circuit 130.

Them pixel circuits 110 (110-1 to 110-m) are provided side by side along the long side 301. Specifically, them pixel circuits 110 (110-1 to 110-m) are provided side by side along the direction in which the long side 301 (example of “first side”) extends from the short side 303 side toward the short side 304 side in the order of the pixel circuit 110-1 (example of “first pixel”), 110-2 (example of “second pixel”), to 110-m of the signal processing circuit 103-1. Furthermore, in contiguous to the pixel circuits 110 (110-1 to 110-m) of the signal processing circuit 103-1, the pixel circuits 110-1, 110-2, . . . , 110-m of the signal processing circuit 103-2 are provided side by side. That is, the 2 m pixel circuits 110 included in the two signal processing circuits 103-1 and 103-2 are successively provided side by side along the long side 301 of the silicon substrate 300 from the short side 303 side toward the short side 304 side.

The m column processing circuits 120 (120-1 to 120-m) are provided side by side with the respective m pixel circuits 110 (110-1 to 110-m) on the long side 302 side thereof. Specifically, the m column processing circuits 120 (120-1 to 120-m) are provided side by side, on the long side 302 side of them pixel circuits 110 (110-1 to 110-m), in order of column processing circuit 120-1, 120-2, . . . , 120-m of the signal processing circuit 103-1 from the short side 303 side toward the short side 304. Furthermore, in contiguous to the column processing circuits 120 (120-1 to 120-m) of the signal processing circuit 103-1, the column processing circuits 120-1, 120-2, . . . , 120-m of the signal processing circuit 103-2 are provided side by side. That is, the 2 m column processing circuits 120 included in the two signal processing circuits 103-1 and 103-2 are provided side by side from the short side 303 side toward the short side 304, on the long side 302 side of the 2 m pixel circuits 110 that are provided side by side along the long side 301, in the silicon substrate 300.

Also, the m column processing circuits 120 (120-1 to 120-m) are respectively electrically connected to them pixel circuits 110 (110-1 to 110-m) (refer to FIG. 9). Specifically, the pixel circuit 110-1 and the column processing circuit 120-1 (example of “first readout circuit”) included in the signal processing circuit 103-1 are electrically connected, and the pixel circuit 110-2 and the column processing circuit 120-2 (example of “second readout circuit”) are electrically connected, that is, the pixel circuits 110-j (j=1 to m) and the column processing circuits 120-j (j=1 to m) are respectively electrically connected. Similarly, the pixel circuits 110-j (j=1 to m) and the column processing circuits 120-j (j=1 to m) included in the signal processing circuit 103-2 are respectively electrically connected.

The m column processing circuits 120 (120-1 to 120-m) each include the amplification circuit 150, the holding circuit 160, and the scanning circuit 170.

The amplification circuit 150 is provided on the pixel circuit 110 side in the column processing circuit 120. Also, the holding circuit 160 is provided on the long side 302 side of the amplification circuit 150, and the scanning circuit 170 is provided on the long side 302 side of the holding circuit 160. That is, in the column processing circuit 120, the amplification circuit 150, the holding circuit 160, and the scanning circuit 170 are provided in this order from the long side 301 side toward the long side 302 side. In other words, the image reading chip 415 is provided with the 2 m pixel circuits 110 (110-1 to 110-m, and 110-1 to 110-m) along the long side 301 in a direction from the short side 303 to the short side 304. Also, the 2 m amplification circuits 150 are provided side by side in a direction from the short side 303 to the short side 304 on the long side 302 side of the 2 m pixel circuits 110 (110-1 to 110-m, and 110-1 to 110-m). Furthermore, the 2 m holding circuits 160 are provided side by side in the direction from the short side 303 to the short side 304 on the long side 302 side of the 2 m amplification circuits 150. Furthermore, the 2 m scanning circuits 170 are provided side by side in the direction from the short side 303 to the short side 304 on the long side 302 side of the 2 m holding circuits 160.

The signal processing circuits 103-1 and 103-2 of the image reading chip 415 in the present embodiment amplify the voltages generated based on light received by the respective pixel circuits 110 using the respective amplification circuits 150, and output, after the amplified voltages are held in the respective holding circuits 160, the amplified voltages as image signals SO based on the operations of the scanning circuits 170. That is, as a result of arranging the pixel circuits 110, and the amplification circuits 150, the holding circuit 160, and the scanning circuit 170 that are included in the column processing circuits 120 in order from the long side 301 side toward the long side 302, the circuit arrangement in accordance with the flow of signals detected by the pixel circuits 110 can be realized, complicated routing of signal lines can be suppressed, and the image signal SO can be stably output.

The amplification circuit 130 is provided side by side with some of the m column processing circuits 120 (120-1 to 120-m) that are provided side by side in the direction from the short side 303 to the short side 304. Specifically, the amplification circuit 130 is provided between a column processing circuit 120-j (j=1 to m−1) and a column processing circuit 120-j+1 (j=1 to m−1). As a result of providing the amplification circuit 130 and the m column processing circuits 120 (120-1 to 120-m) side by side in this way, the area of the silicon substrate 300 in the image reading chip 415 can be effectively utilized, and the chip size of the image reading chip 415 can be reduced.

The drive control circuit 310 includes the timing control circuit 100 and the driving circuit 101.

The drive control circuit 310 is provided side by side with the signal processing circuit 103-1 on the short side 303. That is, the drive control circuit 310 (example of “control circuit”) is provided side by side with m column processing circuits 120 (120-1 to 120-m) included in the signal processing circuit 103-1 along a direction in which the long side 301 extends.

Here, in the present embodiment, the column processing circuits 120 (120-1 to 120-m) included in the signal processing circuit 103-1 are arranged in order of selection by the scan signal SCA output from the timing control circuit 100, the column processing circuit 120-1 that is to be selected first being on the drive control circuit 310 side. That is, the distance between the drive control circuit 310 (example of “control circuit”) and the scanning circuit 170 (example of “first scanning circuit”) included in the column processing circuit 120-1 is shorter than the distance between the drive control circuit 310 and the scanning circuit 170 (example of “second scanning circuit”) included in the column processing circuit 120-2. Furthermore, in the image reading chip 415 in the present embodiment, the drive control circuit 310 is preferably provided at the substrate end on the short side 303 side of the silicon substrate 300. That is, the drive control circuit 310 (example of “control circuit”) is not provided between the scanning circuit 170 (example of “first scanning circuit”) included in the column processing circuit 120-1 and the scanning circuit 170 (example of “second scanning circuit”) included in the column processing circuit 120-2. As a result of such an arrangement, the interconnects for transmitting the scan signal SCA may be provided such that the scan signal SCA is sequentially transmitted to the adjacent column processing circuit 120-i (i=1 to m) from the drive control circuit 310 provided on the short side 303 side. Therefore, the number of interconnects, of the control signals output from the drive control circuit 310 to the column processing circuits 120-i (i=1 to m) formed in the silicon substrate 300, that are laid out from the short side 303 toward short side 304 needs only be the same as the number of control signals, and the interconnects can be easily laid out, and are unlikely to be affected by other signals.

Also, in the present embodiment, the drive control circuit 310 is not provided between the amplification circuit 150 included in the column processing circuit 120-1 and the amplification circuit 150 provided in the column processing circuit 120-2. That is, the drive control circuit 310 is laid out such that the distance between the drive control circuit 310 (example of “control circuit”) and the short side 303 (example of “second side”) is shorter than the distance between the short side 303 and the amplification circuit 150 (example of “first amplification circuit”) included in the column processing circuit 120-1, and the distance between the drive control circuit 310 and the short side 303 is shorter than the distance between the short side 303 and the amplification circuit 150 (example of “second amplification circuit”) included in the column processing circuit 120-2. In other words, the drive control circuit 310 is provided at the substrate end on the short side 303 side of the silicon substrate 300.

The amplification circuit 150 amplifies a weak signal output from the pixel circuit 110. Therefore, it is possible that the image signal OS output from the image reading chip 415 will change due to small differences caused by variations in manufacturing or the like. According to the present embodiment, it is possible to lay out the circuits such that another constituent element is not included between each of the adjacent amplification circuits 150 in the m column processing circuits 120 (120-1 to 120-m) included in the two signal processing circuits 103-1 and 103-2. Accordingly, the two signal processing circuits 103-1 and 103-2 can be formed on the silicon substrate so as to have the same configuration, and the variation in characteristics due to the variation in manufacturing can be suppressed. That is, according to the image reading chip 415 in the present embodiment, the difference in characteristics between the two signal processing circuits 103-1 and 103-2 due to variations in manufacturing can be reduced, and as a result, the difference in characteristics between the 2 m column processing circuits 120 (120-1 to 120-m, and 120-1 to 120-m) can be reduced.

The reference voltage generation circuit 320 is provided on the short side 304 of the signal processing circuit 103-2. The reference voltage generation circuit 320 generates a reference voltage and the like based on the second voltage Vin2 input from a later-described second voltage input electrode 337 (example of “constant voltage terminal”). The reference voltage is input to the 2 m column processing circuits 120 (120-1 to 120-m, and 120-1 to 120-m) in common. Note that the reference voltage generation circuit 320 may be configured to be constituted by a regulator or the like, for example, and generate a plurality of reference voltages.

The input/output portion 330 is provided on the long side 302 side of the two signal processing circuits 103-1 and 103-2, and constituted by a plurality of electrodes and an image signal output circuit 339, along the long side 302. Specifically, the input/output portion 330 includes, from the short side 303 side toward the short side 304 side along the long side 302, a chip enable signal output electrode 331, a chip enable signal input electrode 332, a resolution setting signal input electrode 333, a clock signal input electrode 334, a first voltage input electrode 335, a first ground electrode 336, the image signal output circuit 339, a second voltage input electrode 337, and a second ground electrode 338 in this order. Note that the input/output portion 330 may be configured to include a plurality of electrodes in addition to the above-described electrodes.

The chip enable signal output electrode 331 is for outputting the chip enable signal CE_out output from the drive control circuit 310 to an image reading chip 415 or a reading control circuit 200 (refer to FIG. 7) of the next stage.

The chip enable signal input electrode 332 is for the image reading chip 415 to receive an input of a chip enable signal CE_in input from an image reading chip 415 or a reading control circuit 200 of the previous stage. The chip enable signal CE_in input to the chip enable signal input electrode 332 is input to the timing control circuit 100 included in the drive control circuit 310 (refer to FIG. 8), as described above.

The resolution setting signal input electrode 333 is for receiving an input of a resolution setting signal RES transmitted from the reading control circuit 200 to the image reading chip 415. The resolution setting signal RES is input to the timing control circuit 100 included in the drive control circuit 310 (refer to FIG. 8) via the resolution setting signal input electrode 333.

The clock signal input electrode 334 is for receiving an input of the clock signal CLK transmitted from the reading control circuit 200 to the image reading chip 415. The clock signal CLK is input to the timing control circuit 100 included in the drive control circuit 310 (refer to FIG. 8) via the clock signal input electrode 334.

In the present embodiment, the electrodes for receiving inputs of or outputting the chip enable signal CE_out, the chip enable signal CE_in, the resolution setting signal RES, and the clock signal CLK that are transmitted to or received from the drive control circuit 310 are provided on the short side 303 side of the input/output portion 330. Also, the drive control circuit 310 to which the above-described signals are input is formed at the chip end of the short side 303 of the silicon substrate 300. That is, the drive control circuit 310 and the electrodes of signals to be transmitted to the drive control circuit 310 can be arranged close to each other. Therefore, in the image reading chip 415 in the present embodiment, it is possible to avoid the layout of interconnects of signals input to the drive control circuit 310 from the input/output portion 330 from becoming complicated.

The first voltage input electrode 335 and the first ground electrode 336 are provided adjacent to each other in the input/output portion 330, and are electrodes for supplying voltages (potentials) to the image reading chip 415. Specifically, the first voltage Vin1 generated by the first voltage generation circuit 421 is supplied to the drive control circuit 310 and the image signal output circuit 339 included in the image reading chip 415 via the first voltage input electrode 335 and the first ground electrode 336. Also, the first voltage input electrode 335 and the first ground electrode 336 are provided between the clock signal input electrode 334 and the image signal output circuit 339. That is, according to the present embodiment, the interconnects between the first voltage input electrode 335, the first ground electrode 336, and the drive control circuit 310 do not intersect the interconnects between the first voltage input electrode 335, the first ground electrode 336, and the image signal output circuit 339, and are short.

The image signal output circuit 339 is constituted by an electrode for outputting the image signal OS to the outside of the image reading chip 415 and the operational amplifier 104 (refer to FIG. 8). That is, the image signal output circuit 339 outputs the image signal OS detected and generated in the image reading chip 415 to the analog front end (AFE) 202 (refer to FIG. 7).

In the present embodiment, the image signal output circuit 339 is provided in the vicinity of the amplification circuit 130 included in the signal processing circuit 103-1, in the input/output portion 330. That is, the distance between the operational amplifier 104 (example of “output circuit”) included in the image signal output circuit 339 and the amplification circuit 130 (example of “third amplification circuit”) included in the signal processing circuit 103-1 is shorter than the distance between the operational amplifier 104 included in the image signal output circuit 339 and the drive control circuit 310.

The image signal output circuit 339 is supplied with the first voltage Vin1 via the first voltage input electrode 335 and the first ground electrode 336. The image signal output circuit 339 is preferably provided in the vicinity of the first voltage input electrode 335 and the first ground electrode 336.

On the other hand, the image signal output circuit 339 receives the image signals SO1 and SO2 from the respective amplification circuits 130 included in the two signal processing circuits 103-1 and 103-2, and outputs the image signal OS. Therefore, the interconnects for transmitting the image signals SO1 and SO2 are preferably formed to be as short as possible in order to suppress interconnect impedance, and the image signal output circuit 339 is preferably provided in the vicinity of at least one of the amplification circuits 130 included in the two signal processing circuits 103-1 and 103-2.

Accordingly, out of the two signal processing circuits 103-1 and 103-2, the image signal output circuit 339 is preferably provided in the vicinity of the amplification circuit 130 included in the signal processing circuit 103-1 provided on the drive control circuit 310 side. As a result, the image signal output circuit 339 can accurately receive the first voltage Vin1 and the image signal SO1 (or image signal SO2) to be input.

The second voltage input electrode 337 and the second ground electrode 338 are provided adjacent to each other, and are electrodes for supplying voltages (potentials) to the image reading chip 415. Specifically, the second voltage Vin2 generated by the second voltage generation circuit 422 is supplied to the amplification circuits 130 respectively included in the two signal processing circuits 103-1 and 103-2 included in the image reading chip 415 and the reference voltage generation circuit 320, via the second voltage input electrode 337 and the second ground electrode 338.

In the present embodiment, the second voltage input electrode 337 and the second ground electrode 338 are provided such that the distance between the second voltage input electrode 337 (example of “constant voltage terminal”) and the column processing circuit 120-1 (example of “first readout circuit”) is shorter than the distance between the second voltage input electrode 337 and the drive control circuit 310 (example of “control circuit”), and the distance between the second voltage input electrode 337 and the column processing circuit 120-2 (example of “second readout circuit”) is shorter than the distance between the second voltage input electrode 337 and the drive control circuit 310.

The second voltage Vin2 is input to the amplification circuits 130 respectively included in the two signal processing circuits 103-1 and 103-2 and the reference voltage generation circuit 320, via the second voltage input electrode 337 and the second ground electrode 338. Also, meanwhile, the first voltage Vin1 is input to the drive control circuit 310 and the image signal output circuit 339, as described above. Furthermore, the amplification circuits 130 respectively included in the two signal processing circuits 103-1 and 103-2 and the reference voltage generation circuit 320 are provided on the short side 304 side of the drive control circuit 310. Accordingly, the second voltage input electrode 337 and the second ground electrode 338 for receiving the input of the second voltage Vin2 are preferably provided on the short side 304 side of the silicon substrate 300, that is, on the side separated from the drive control circuit 310, in the input/output portion 330. Accordingly, the interconnect to which the first voltage Vin1 is applied does not intersect the interconnect to which the second voltage Vin2 is applied, and the mutual interference is reduced, and as a result, the power can be accurately supplied. Also, the length of the interconnect to which the second voltage Vin2 is applied can be reduced, and interference with another control signal or the like can be suppressed, and as a result, image reading accuracy can be improved.

5. Action/Effect

As described above, in the scanner unit (image reading device) 3 of the present embodiment, them column processing circuits 120 (120-1 to 120-m) including the column processing circuit 120-1 and the column processing circuit 120-2 and the drive control circuit 310 are provided side by side along the direction in which the long side 301 extends from the short side 303 side toward the short side 304, in the image reading chip 415. That is, the interconnects of the control signals (such as transfer signal TX and readout signal READ) for controlling the m column processing circuits 120 (120-1 to 120-m) that are output from the drive control circuit 310 need only be provided in a direction in which the long side 301 extends, and unnecessary routing of the interconnects or the like does not occur. Therefore, impedance of interconnects of the control signals can be reduced, and the image can be accurately read.

Also, in the scanner unit (image reading device) 3 of the present embodiment, the m pixel circuits 110 (110-1 to 110-m) including the pixel circuit 110-1 and the pixel circuit 110-2 are provided side by side along the long side 301 from the short side 303 side to the short side 304, in the image reading chip 415. That is, the pixel signal PIXO1 output from the pixel circuit 110-1 is transmitted to the column processing circuit 120-1 from the long side 301 side toward the long side 302, and the pixel signal PIXO2 output from the pixel circuit 110-2 is transmitted to the column processing circuit 120-2 from the long side 301 side toward the long side 302. That is, the interconnects for transmitting the control signals for controlling the m column processing circuits 120 (120-1 to 120-m) and the interconnects for transmitting the pixel signals PIXOj (j=1 to m) respectively detected in the pixel circuits 110-j (j=1 to m) are not routed in parallel. Accordingly, the stray capacitances that occur between the interconnects can be reduced. Therefore, the parasitic impedances of interconnects of the control signals can be reduced, and images can be accurately read.

Also, in the scanner unit (image reading device) 3 of the present embodiment, in them column processing circuits 120 (120-1 to 120-m) of the image reading chip 415, after the column processing circuit 120-j (j=1 to m) has output the image signal VDOj (j=1 to m−1), the column processing circuit 120-j+1 (j=1 to m) operates so as to output the image signal VDOj (j=1 to m−1). Also, the m column processing circuits 120 (120-1 to 120-m) are arranged in order of the column processing circuit 120-1, 120-2, . . . , 120-m from the drive control circuit 310 side toward the short side 304. That is, the column processing circuit 120 that operates earlier is provided on the drive control circuit 310. As a result of this arrangement, it is possible to avoid the interconnects for transmitting control signals for controlling the m column processing circuits 120 (120-1 to 120-m) that are output from the drive control circuit 310 from becoming complicated, and unnecessary interconnects can be reduced, and therefore the impedances of interconnects of the control signals can be reduced, and images can be accurately read.

Also, in the scanner unit (image reading device) 3 of the present embodiment, lengths of the interconnects from output terminals of the amplification circuits 130 respectively provided in the two signal processing circuits 103-1 and 103-2 to an input terminal of the operational amplifier 104, in the image reading chip 415, can be reduced, and the impedances of the interconnects can be reduced. As a result, the signal can be accurately output from the output circuit.

6. Modifications

The scanner unit 3 in the present embodiment is configured such that a document P placed on the platen T is read, as shown in FIGS. 1 and 2, but may be a conveyance type scanner unit including an ADF (auto document feeder) and the like. Furthermore, the scanner unit 3 may be configured as a double-side reading type scanner that includes the image sensor modules 41 on both the surface and back surface of the document P, and reads the surface and back surface of the document P at the same time.

Also, in the present embodiment, the scanner unit 3 having a divided optical reduction system has been described in which the plurality of image reading chips 415 are mounted on the image sensor module 41, divided images of the document P are respectively reduced, and read by the plurality of image reading chips 415. However, the scanner unit 3 may be configured as a so-called optical reduction system in which the document P is read by one image reading chip 415.

Also, in the present embodiment, the electrodes for the chip enable signal CE_in and the chip enable signal CE_out that are provided in the image reading chip are provided on the short side 303 side, in the layout of the image reading chip 415 shown in FIG. 11. The electrode for the chip enable signal CE_in may be provided on the short side 303 side, and the chip enable signal CE_out may be provided on the short side 304 side, for example.

The chip enable signal CE_in is a signal received from an image reading chip 415 (or reading control circuit 200) of the previous stage, and the chip enable signal CE_out is a signal that is output to an image reading chip 415 (or reading control circuit 200) of the next stage. According to the present embodiment, the plurality of image reading chips 415 are arranged side by side on the module substrate 414 in one-dimensional direction. Therefore, as a result of providing the electrode of the chip enable signal CE_in on the short side 303, and the electrode of the chip enable signal CE_out on the short side 304, it is possible to avoid the wiring used for transmitting signals between different image reading chips 415 from becoming complicated, the impedances in wiring in the module substrate 414 can be reduced.

In these modifications as well, effects similar to those of the above-mentioned embodiment can be achieved.

Although the embodiment and the modifications have been described above, the invention is not limited to these embodiment and the modifications, and can be carried out in various modes without departing from the gist of the invention. For example, the embodiment and the modifications can be combined as appropriate.

The invention includes substantially the same configurations (configurations with the same functions, methods, and results, or configurations with the same object and effect, for example) as the configurations described in the embodiment. The invention includes configurations in which an unessential part of the configurations described in the embodiment is replaced. The invention also includes configurations that achieve the same effect as that of the configurations described in the embodiment, or configurations that can achieve the same object as that of the configurations described in the embodiment. The invention also includes configurations obtained by adding a known technique to the configurations described in the embodiment.

This application claims priority from Japanese Patent Application No. 2017-047456 filed in the Japanese Patent Office on Mar. 13, 2017, the entire disclosure of which is hereby incorporated by reference in its entirely.

What is claimed is:

1. An image reading device comprising:
a first image reading chip that reads an image; and
an optical unit that forms a reduced image of the image on the first image reading chip,
wherein the first image reading chip includes:
a first side;
a second side that is shorter than the first side;
a first pixel that includes a first photodetector that receives light of a reduced image of the image and performs photoelectric conversion, and generates a first pixel signal;
a second pixel that includes a second photodetector that receives light of a reduced image of the image and performs photoelectric conversion, and generates a second pixel signal;
a first readout circuit that is electrically connected to the first pixel and outputs a first readout signal based on the first pixel signal; and
a second readout circuit that is electrically connected to the second pixel and outputs a second readout signal based on the second pixel signal; and
a control circuit that controls operations of the first readout circuit and the second readout circuit,
wherein the first pixel and the second pixel are provided side by side in a direction in which the first side extends, and
the first readout circuit, the second readout circuit, and the control circuit are provided side by side in the direction in which the first side extends.

2. The image reading device according to claim 1,
wherein the first readout circuit includes a first scanning circuit that controls an output timing of the first readout signal,
the second readout circuit includes a second scanning circuit that controls an output timing of the second readout signal,
after the first photodetector and the second photodetector receive light of an reduced image of the image, the timing at which the first readout signal is output by the first scanning circuit is earlier than the timing at which the second readout signal is output by the second scanning circuit, and
the distance between the control circuit and the first scanning circuit is shorter than the distance between the control circuit and the second scanning circuit.

3. The image reading device according to claim 2, wherein the control circuit is not provided between the first scanning circuit and the second scanning circuit.

4. The image reading device according to claim 1,
wherein the first readout circuit includes a first amplification circuit that amplifies the first pixel signal and generates the first readout signal,
the second readout circuit includes a second amplification circuit that amplifies the second pixel signal and generates the second readout signal,
a distance between the second side and the control circuit is shorter than a distance between the second side and the first amplification circuit, and
the distance between the second side and the control circuit is shorter than a distance between the second side and the second amplification circuit.

5. The image reading device according to claim 1,
wherein the first image reading chip includes a constant voltage terminal to which a constant voltage is supplied,
a distance between the constant voltage terminal and the first readout circuit is shorter than a distance between the constant voltage terminal and the control circuit, and
a distance between the constant voltage terminal and the second readout circuit is shorter than the distance between the constant voltage terminal and the control circuit.

6. The image reading device according to claim 1,
wherein the first image reading chip includes:
a third amplification circuit that amplifies a signal output from at least one of the first readout circuit and the second readout circuit, and generates an amplified signal; and
an output circuit that generates, based on the amplified signal, an output signal to be output to the outside of the first image reading chip, and
a distance between the output circuit and the third amplification circuit is shorter than a distance between the output circuit and the control circuit.

7. The image reading device according to claim 1, further comprising a second image reading chip,
wherein the image includes a first partial image and a second partial image,
the optical unit
forms a reduced image of the first partial image on the first image reading chip, and
forms a reduced image of the second partial image on the second image reading chip.

8. A semiconductor device comprising:
a first pixel that includes a first photodetector that receives light of a reduced image of an image and performs photoelectric conversion, and generates a first pixel signal;
a second pixel that includes a second photodetector that receives light of a reduced image of the image and performs photoelectric conversion, and generates a second pixel signal;
a first readout circuit that is electrically connected to the first pixel and reads out the first pixel signal;
a second readout circuit that is electrically connected to the second pixel and reads out the second pixel signal;
a control circuit that controls operations of the first readout circuit and the second readout circuit;
a first side; and
a second side that is shorter than the first side,
wherein the first pixel and the second pixel are provided side by side in a direction in which the first side extends, and
the first readout circuit, the second readout circuit, and the control circuit are provided side by side in the direction in which the first side extends.
